(19) United States
(12) Patent Application Publication
(10) Pub. No.: US 2025/0185512 A1
(43) Pub. Date: Jun. 5, 2025

(54) THERMOELECTRIC CONVERSION ELEMENT AND METHOD FOR MANUFACTURING THERMOELECTRIC CONVERSION ELEMENT

(71) Applicant: Panasonic Intellectual Property Management Co., Ltd., Osaka (JP)

(72) Inventors: Kouhei TAKAHASHI, Osaka (JP); Masaki FUJIKANE, Osaka (JP); Kunihiko NAKAMURA, Osaka (JP); Atsushi HIMENO, Osaka (JP); Naoki TAMBO, Kyoto (JP); Hiroyuki TANAKA, Nara (JP)

(21) Appl. No.: 19/046,241

(22) Filed: Feb. 5, 2025

Related U.S. Application Data
(63) Continuation of application No. PCT/JP2023/030824, filed on Aug. 25, 2023.

(30) Foreign Application Priority Data
Aug. 31, 2022 (JP) 2022-138390

(51) Int. Cl. H10N 10/17; H10N 10/01

(52) U.S. Cl. CPC H10N 10/17; H10N 10/01

(57) ABSTRACT

A thermoelectric conversion element includes a substrate, a thermocouple, and a thermal insulator. The thermocouple includes a thin-film-shaped thermoelectric member and an electroconductive member. The thermoelectric member and the electroconductive member are arranged along a principal surface of a substrate. The electroconductive member contains at least one selected from the group consisting of metal and a metal compound. The thermal insulator is in contact with the electroconductive member. A thermal conductivity of the thermal insulator is lower than a thermal conductivity of the electroconductive member.

This application is a continuation of PCT/JP2023/030824 filed on Aug. 25, 2023, which claims foreign priority of Japanese Patent Application No. 2022-138390 filed on Aug. 31, 2022, the entire contents of both of which are incorporated herein by reference.

### BACKGROUND OF THE INVENTION

### 1. Field of the Invention

The present disclosure relates to a thermoelectric conversion element and a method for manufacturing a thermoelectric conversion element.

### 2. Description of Related Art

Thermoelectric conversion is a technology of directly converting heat energy to electric energy using the Seebeck effect in which an electromotive force is generated in proportion to a temperature difference applied between both ends of a material. Alternatively, thermoelectric conversion is a technology of converting electric energy to heat energy using the Peltier effect in which a temperature difference arises between both ends of a material by current generated in the material.

The performance of a thermoelectric conversion element is evaluated by a performance index Z or a nondimensionalized performance index ZT which is a product of the performance index Z and an absolute temperature T. ZT is represented as ZT=S²T/ρκ, using a Seebeck coefficient S, an electrical resistivity ρ, and a thermal conductivity κ of a thermoelectric material used for the thermoelectric conversion element. Therefore, using a thermoelectric material of which the Seebeck coefficient S is high and the electrical resistivity ρ and the thermal conductivity κ are low is desirable in terms of enhancement in thermoelectric conversion performance.

As the thermoelectric conversion element, a TT-type thermoelectric conversion element is known. In the TT-type thermoelectric conversion element, a p-type thermoelectric member having a positive Seebeck coefficient and an n-type thermoelectric member having a negative Seebeck coefficient are connected electrically in series and connected thermally in parallel, whereby a thermocouple is formed.

As the thermoelectric conversion element, a uni-leg type thermoelectric conversion element is also known. In the uni-leg type thermoelectric conversion element, only one of a p-type thermoelectric member and an n-type thermoelectric member is used as a thermoelectric member, and by a metal plate, each thermoelectric member is connected electrically in series and connected thermally in parallel. For example, JP 2015-70217 and JP 2016-111309 describe uni-leg type thermoelectric conversion elements. In the TT-type thermoelectric conversion element, it is important to use a p-type thermoelectric member and an n-type thermoelectric member that are close to each other in properties such as an electrical resistivity, a thermal conductivity, and a Seebeck coefficient. On the other hand, in the uni-leg type thermoelectric conversion element, since only one of a p-type thermoelectric member and an n-type thermoelectric member is used as the thermoelectric member, there are fewer constraints on selection of the thermoelectric member.

### SUMMARY OF THE INVENTION

In the above technologies, configuring a uni-leg type thermoelectric conversion element using a thin-film-shaped thermoelectric member is not assumed.

Accordingly, the present disclosure provides a technology that is advantageous in terms of thermoelectric conversion performance while using a thin-film-shaped thermoelectric member in a uni-leg type thermoelectric conversion element.

The present disclosure provides the following thermoelectric conversion element.

A thermoelectric conversion element including:
a substrate;
a thermocouple including a thin-film-shaped thermoelectric member and an electroconductive member arranged along a principal surface of the substrate; and
a thermal insulator in contact with the electroconductive member, wherein
the electroconductive member contains at least one selected from the group consisting of metal and a metal compound, and
a thermal conductivity of the thermal insulator is lower than a thermal conductivity of the electroconductive member.

The thermoelectric conversion element of the present disclosure is configured as a uni-leg type thermoelectric conversion element including a thin-film-shaped thermoelectric member, and is advantageous in terms of thermoelectric conversion performance.

### BRIEF DESCRIPTION OF THE DRAWINGS

FIG. 1A is a sectional view schematically showing an example of a thermoelectric conversion element of embodiment 1.

FIG. 1B is a sectional view schematically showing another example of the thermoelectric conversion element of embodiment 1.

FIG. 2A is a plan view showing an example of a thermoelectric member of embodiment 1.

FIG. 2B is a plan view showing another example of the thermoelectric member of embodiment 1.

FIG. 2C is a plan view showing still another example of the thermoelectric member of embodiment 1.

FIG. 2D is a plan view showing still another example of the thermoelectric member of embodiment 1.

FIG. 2E is a plan view showing still another example of the thermoelectric member of embodiment 1.

FIG. 2F is a plan view showing still another example of the thermoelectric member of embodiment 1.

FIG. 3A is a plan view showing an example of an electroconductive member of embodiment 1.

FIG. 3B is a plan view showing another example of the electroconductive member of embodiment 1.

FIG. 3C is a plan view showing still another example of the electroconductive member of embodiment 1.

FIG. 3D is a plan view showing still another example of the electroconductive member of embodiment 1.

FIG. 3E is a plan view showing still another example of the electroconductive member of embodiment 1.

FIG. 3F is a plan view showing still another example of the electroconductive member of embodiment 1.

FIG. 3G is a plan view showing still another example of the electroconductive member of embodiment 1.

FIG. 3H is a plan view showing still another example of the electroconductive member of embodiment 1.

FIG. 4A is a sectional view of a thermocouple taken along line IVA-IVA in FIG. 1A.

FIG. 4B is a sectional view showing another example of arrangement of the thermoelectric member and the electroconductive member in the thermocouple of embodiment 1.

FIG. 4C is a sectional view showing still another example of arrangement of the thermoelectric member and the electroconductive member in the thermocouple of embodiment 1.

FIG. 4D is a sectional view showing still another example of arrangement of the thermoelectric member and the electroconductive member in the thermocouple of embodiment 1.

FIG. 4E is a sectional view showing still another example of arrangement of the thermoelectric member and the electroconductive member in the thermocouple of embodiment 1.

FIG. 5A is a sectional view showing a method for manufacturing the thermoelectric conversion element of embodiment 1.

FIG. 5B is a sectional view showing the method for manufacturing the thermoelectric conversion element of embodiment 1.

FIG. 5C is a sectional view showing the method for manufacturing the thermoelectric conversion element of embodiment 1.

FIG. 5D is a sectional view showing the method for manufacturing the thermoelectric conversion element of embodiment 1.

FIG. 5E is a sectional view showing the method for manufacturing the thermoelectric conversion element of embodiment 1.

FIG. 5F is a sectional view showing the method for manufacturing the thermoelectric conversion element of embodiment 1.

FIG. 5G is a sectional view showing the method for manufacturing the thermoelectric conversion element of embodiment 1.

FIG. 5H is a sectional view showing the method for manufacturing the thermoelectric conversion element of embodiment 1.

FIG. 5I is a sectional view showing the method for manufacturing the thermoelectric conversion element of embodiment 1.

FIG. 5J is a sectional view showing the method for manufacturing the thermoelectric conversion element of embodiment 1.

FIG. 5K is a sectional view showing the method for manufacturing the thermoelectric conversion element of embodiment 1.

FIG. 5L is a sectional view showing the method for manufacturing the thermoelectric conversion element of embodiment 1.

FIG. 5M is a sectional view showing the method for manufacturing the thermoelectric conversion element of embodiment 1.

FIG. 5N is a sectional view showing the method for manufacturing the thermoelectric conversion element of embodiment 1.

FIG. 5O is a sectional view showing the method for manufacturing the thermoelectric conversion element of embodiment 1.

FIG. 6A is a sectional view schematically showing an example of a thermoelectric conversion element of embodiment 2.

FIG. 6B is a sectional view schematically showing another example of the thermoelectric conversion element of embodiment 2.

FIG. 7A is a sectional view of the thermocouple taken along line VIIA-VIIA in FIG. 6A.

FIG. 7B is a sectional view showing another example of arrangement of a thermoelectric member and an electroconductive member in the thermocouple of embodiment 2.

FIG. 7C is a sectional view showing still another example of arrangement of the thermoelectric member and the electroconductive member in the thermocouple of embodiment 2.

FIG. 7D is a sectional view showing still another example of arrangement of the thermoelectric member and the electroconductive member in the thermocouple of embodiment 2.

FIG. 8A is a sectional view showing a method for manufacturing the thermoelectric conversion element of embodiment 2.

FIG. 8B is a sectional view showing the method for manufacturing the thermoelectric conversion element of embodiment 2.

FIG. 8C is a sectional view showing the method for manufacturing the thermoelectric conversion element of embodiment 2.

FIG. 8D is a sectional view showing the method for manufacturing the thermoelectric conversion element of embodiment 2.

FIG. 8E is a sectional view showing the method for manufacturing the thermoelectric conversion element of embodiment 2.

FIG. 8F is a sectional view showing the method for manufacturing the thermoelectric conversion element of embodiment 2.

FIG. 8G is a sectional view showing the method for manufacturing the thermoelectric conversion element of embodiment 2.

FIG. 8H is a sectional view showing the method for manufacturing the thermoelectric conversion element of embodiment 2.

FIG. 8I is a sectional view showing the method for manufacturing the thermoelectric conversion element of embodiment 2.

FIG. 8J is a sectional view showing the method for manufacturing the thermoelectric conversion element of embodiment 2.

FIG. 8K is a sectional view showing the method for manufacturing the thermoelectric conversion element of embodiment 2.

FIG. 8L is a sectional view showing the method for manufacturing the thermoelectric conversion element of embodiment 2.

### DETAILED DESCRIPTION

(Finding on which the Present Disclosure is Based)

In a uni-leg type thermoelectric conversion element, it is considered that a metal plate for electrically connecting a thermoelectric member has a high thermal conductance relative to the thermoelectric member. Therefore, in the uni-leg type thermoelectric conversion element, the thermal conductance of the entire element is likely to become higher than in a TT-type thermoelectric conversion element. This cannot be considered advantageous in terms of thermoelectric conversion performance.

In the uni-leg type thermoelectric conversion element, a thermal conductance Gₜ of the thermoelectric member is represented as Gₜ=κₜ×Aₜ/Lₜ, using a thermal conductivity κₜ of a material forming the thermoelectric member, an area Aₜ of an end surface forming one end in the heat flow direction of the thermoelectric member, and a dimension Lₜ in the heat flow direction of the thermoelectric member. A thermal conductance Gₘ of the metal plate which forms a thermocouple together with the thermoelectric member is represented as Gₘ=κₘ×Aₘ/Lₘ, using a thermal conductivity κm of a material of the metal plate, an area Aₘ of an end surface forming one end in the heat flow direction of the metal plate, and a dimension Lₘ in the heat flow direction of the metal plate. In the uni-leg type thermoelectric conversion element, the dimension Lₜ and the dimension Lₘ can be adjusted to values that are the same or close to each other. Therefore, by making the area Aₘ of the metal plate smaller than the area Aₜ of the thermoelectric member, the thermal conductance of the electroconductive member which is a member forming a thermocouple together with the thermoelectric member in the uni-leg type thermoelectric conversion element is likely to become low.

In a thermoelectric conversion element including a thermoelectric member formed by a bulk obtained through a manufacturing process including cutting work, it is difficult to manufacture a metal plate which forms a thermocouple together with a thermoelectric member, so as to have a fine structure. Accordingly, it is conceivable to manufacture thermoelectric conversion elements including a thin-film-shaped thermoelectric member by using a semiconductor manufacturing process or the like. In this case, a fine structure is likely to be obtained by a method such as lithography. Accordingly, it is conceivable to electrically connect each thin-film-shaped thermoelectric member using, instead of the metal plate, an electroconductive member of which the area of an end surface at one end in the heat flow direction is small and which contains at least one selected from the group consisting of metal and a metal compound. Thus, the thermal conductance of the member electrically connecting each thermoelectric member in the uni-leg type thermoelectric conversion element can be reduced. On the other hand, in order to form an electroconductive member having a fine structure, a process with a process node involving high manufacturing cost is needed, depending on the degree of fineness of the structure. In addition, it is difficult to enlarge the dimension of the electroconductive member in a direction perpendicular to a principal surface of a substrate. Accordingly, the present inventors have studied intensively on a technology that can reduce the thermal conductance of a member for electrically connecting each thermoelectric member while reducing the manufacturing cost, using a thin-film-shaped thermoelectric member in a uni-leg type thermoelectric conversion element. As a result, the present inventors have finally completed the thermoelectric conversion element of the present disclosure.

### Embodiments of the Present Disclosure

Hereinafter, embodiments of the present disclosure will be described with reference to the drawings. The embodiments described below are all comprehensive or specific examples. The numerical values, shapes, materials, components, arrangement positions of the components, connection forms, process conditions, steps, order of the steps, etc., shown in the following embodiments are examples, and are not intended to limit the present disclosure. In addition, among the components in the following embodiments, the components that are not described in the independent claims that represent broadest concepts are described as discretionary components. Each drawing is a schematic diagram, and is not necessarily exactly illustrated.

### Embodiment 1

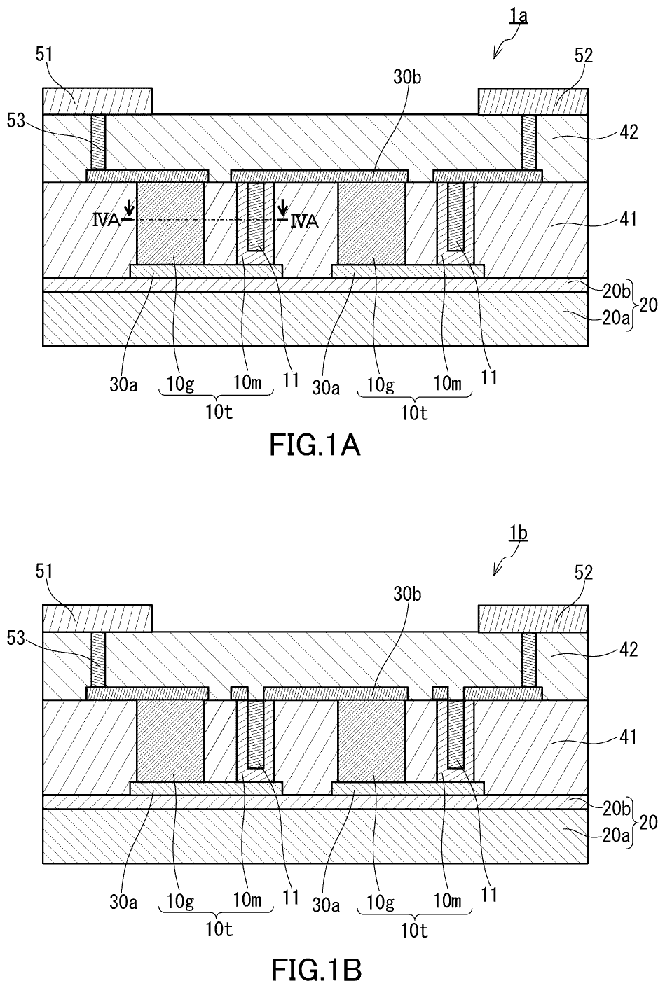

FIG. 1A is a sectional view schematically showing an example of a thermoelectric conversion element of embodiment 1. As shown in FIG. 1A, a thermoelectric conversion element 1a includes a substrate 20, thermocouples 10t, and thermal insulators 11. Each thermocouple 10t includes a thin-film-shaped thermoelectric member 10g and an electroconductive member 10m. The thermoelectric member 10g and the electroconductive member 10m are arranged along a principal surface of the substrate 20. Each of the thermoelectric member 10g and the electroconductive member 10m extends along the principal surface of the substrate 20, for example. The electroconductive member 10m contains at least one selected from the group consisting of metal and a metal compound. The thermal insulator 11 is in contact with the electroconductive member 10m. The thermal conductivity of the thermal insulator 11 is lower than the thermal conductivity of the electroconductive member 10m. Owing to the thermal insulator 11, the volume of the electroconductive member 10m is likely to become small even if the electroconductive member 10m is not formed as a fine structure having a dimension of 1 μm or smaller in a direction parallel to the principal surface of the substrate 20, for example. Thus, the thermal conductance of the electroconductive member 10m is likely to become low. As a result, the thermoelectric conversion performance of the thermoelectric conversion element 1a is likely to become high. As used herein, the thermal conductivity is a value at 25° C. For forming the fine structure having a dimension of 1 μm or smaller, a process with a process node involving high manufacturing cost may be needed.

A material forming the thermoelectric member 10g is not limited to a specific material. The material may be a thermoelectric material having a positive Seebeck coefficient or a thermoelectric material having a negative Seebeck coefficient. The material forming the thermoelectric member 10g is desirably a semiconductor material in which carriers serving for electric conduction can be adjusted to either holes or electrons by doping, for example. Examples of such a semiconductor material are Si, SiGe, SiC, GaAs, InAs, InSb, InP, GaN, ZnO, and BiTe. The material forming the thermoelectric member 10g may be another material. The material forming the thermoelectric member 10g may be a single-crystal material, a polycrystal material, or an amorphous material.

The thickness of the thermoelectric member 10g in the direction perpendicular to the principal surface of the substrate 20 is not limited to a specific thickness. The thickness is 100 nm or more and 10 μm or smaller, for example. The carrier density of the thermoelectric member 10g is not limited to a specific value. The carrier density is in a range of 1×10¹⁹ cm⁻³ to 1×10²¹ cm⁻³, for example.

The metal or the metal compound contained in the electroconductive member 10m is not limited to specific metal or a specific metal compound. Examples of the metal and the metal compound are materials, such as Al, Cu, TIN, and TaN, used in a semiconductor manufacturing process.

The thermal conductivity of the electroconductive member 10m is not limited to a specific value as long as the thermal conductivity of the thermal insulator 11 is lower than the thermal conductivity of the electroconductive member 10m. The thermal conductivity of the electroconductive member 10m is 15 Wm⁻¹K⁻¹ or higher and 400 Wm⁻¹K⁻¹ or lower, for example.

The dimension of the electroconductive member 10m in the direction perpendicular to the principal surface of the substrate 20 is not limited to a specific value. The dimension can vary in accordance with the thickness of the thermoelectric member 10g. The dimension is 100 nm or greater and 10 μm or smaller, for example.

The maximum dimension of the electroconductive member 10m in a direction parallel to the principal surface of the substrate 20 is not limited to a specific value. The maximum dimension is 2 μm or greater and 50 μm or smaller, for example. With this configuration, the electroconductive member 10m can be formed without using a process with a process node involving high manufacturing cost, so that the manufacturing cost of the thermoelectric conversion element 1a is less likely to become high.

The thermal conductivity of the thermal insulator 11 is not limited to a specific value as long as the thermal conductivity thereof is lower than that of the electroconductive member 10m. The thermal conductivity of the thermal insulator 11 is 10 Wm⁻¹K⁻¹ or lower, for example. In this case, the thermal conductance of the structure including the electroconductive member 10m and the thermal insulator 11 is likely to become low, so that the thermal conductance of the entire thermoelectric conversion element 1a is likely to become low. Therefore, the thermoelectric conversion performance of the thermoelectric conversion element 1a is likely to become higher. The thermal conductivity of the thermal insulator 11 may be 20 Wm⁻¹K⁻¹ or lower, or 10 Wm⁻¹K⁻¹ or lower. The thermal conductivity of the thermal insulator 11 is 0.1 Wm⁻¹K⁻¹ or higher, for example.

The thermal insulator 11 contains an amorphous material, for example. In this case, the thermal conductivity of the thermal insulator 11 is likely to become low, so that the thermal conductance of the structure including the electroconductive member 10m and the thermal insulator 11 is likely to become low. The thermal insulator 11 may contain a polycrystal material. A material forming the thermal insulator 11 is not limited to a specific material as long as the thermal conductivity of the thermal insulator 11 is lower than the thermal conductivity of the electroconductive member 10m. Examples of the material forming the thermal insulator 11 are oxides such as SiO₂ and Al₂O₃, and metal glass.

In the thermoelectric conversion element 1a, the ratio of the volume of the thermal insulator 11 to the sum of the volumes of the electroconductive member 10m and the thermal insulator 11 is not limited to a specific value. The ratio is 50% to 90%, for example. With this configuration, the thermal conductance of the structure including the electroconductive member 10m and the thermal insulator 11 is likely to become lower, so that the thermal conductance of the entire thermoelectric conversion element 1a is likely to become lower. In addition, the electroconductive member 10m is likely to have a desired electric conductivity.

As shown in FIG. 1A, in the thermoelectric conversion element 1a, the substrate 20 includes a base 20a and a foundation insulation film 20b, for example. A first wiring 30a is disposed on the foundation insulation film 20b. The thermoelectric members 10g and the electroconductive members 10m are disposed on the first wiring 30a. A second wiring 30b is disposed on the thermoelectric members 10g and the electroconductive members 10m. One-end surfaces of the thermoelectric members 10g and the electroconductive members 10m in the direction perpendicular to the principal surface of the substrate 20 are electrically connected to the first wiring 30a. Other-end surfaces of the thermoelectric members 10g and the electroconductive members 10m in the direction perpendicular to the principal surface of the substrate 20 are electrically connected to the second wiring 30b.

As shown in FIG. 1A, the thermal insulators 11 are covered by the second wiring 30b, for example. FIG. 1B is a sectional view schematically showing another example of the thermoelectric conversion element of embodiment 1. A thermoelectric conversion element 1b shown in FIG. 1B is configured in the same manner as the thermoelectric conversion element 1a, except for specifically described parts. As shown in FIG. 1B, the thermal insulators 11 may not be covered by the second wiring 30b.

The thermoelectric members 10g and the electroconductive members 10m are connected electrically in series via the first wiring 30a and the second wiring 30b. Thus, the thermocouples 10t are configured by the thermoelectric members 10g and the electroconductive members 10m.

As shown in FIG. 1A, the thermoelectric conversion element 1a further includes a first interlayer insulation film 41 and a second interlayer insulation film 42, for example. The first interlayer insulation film 41 is disposed between the first wiring 30a and the second wiring 30b in the direction perpendicular to the principal surface of the substrate 20. The first interlayer insulation film 41 is formed so as to fill a gap between the thermoelectric member 10g and the electroconductive member 10m and a space around the thermoelectric member 10g and the electroconductive member 10m. The second interlayer insulation film 42 is formed so as to cover the second wiring 30b.

The thermoelectric conversion element 1a includes a plurality of plugs 53, for example. The plugs 53 extend through the second interlayer insulation film 42 in the direction perpendicular to the principal surface of the substrate 20. The plugs 53 are disposed on the second wiring 30b and are electrically connected to the second wiring 30b.

The thermoelectric conversion element 1a includes a first electrode pad 51 and a second electrode pad 52, for example. The first electrode pad 51 and the second electrode pad 52 are electrically connected to different plugs 53, respectively. Thus, between the first electrode pad 51 and the second electrode pad 52, the thermocouples 10t are electrically connected to the first electrode pad 51 and the second electrode pad 52.

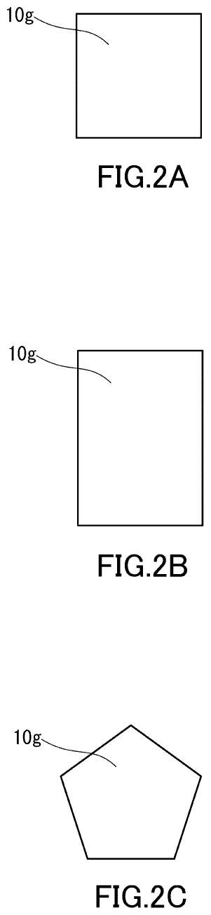

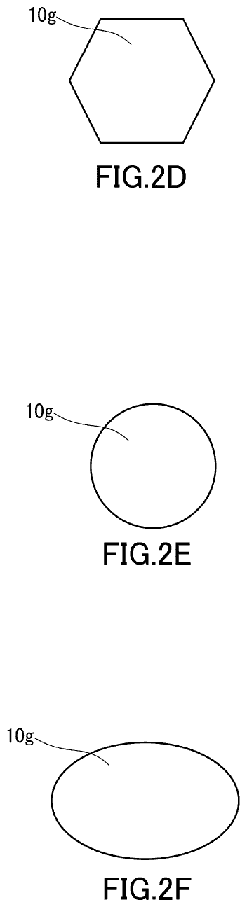

The shape of the thermoelectric member 10g is not limited to a specific shape. FIG. 2A to FIG. 2F are plan views showing examples of the thermoelectric member 10g. As shown in FIG. 2A to FIG. 2D, the thermoelectric member 10g may have a quadrangular shape such as a square shape and a rectangular shape, a pentagonal shape, a hexagonal shape, or another polygonal shape. As shown in FIG. 2E and FIG. 2F, the thermoelectric member 10g may have a circular shape or an elliptic shape.

The arrangement of the thermal insulator 11 and the electroconductive member 10m is not limited to specific arrangement as long as the thermal insulator 11 is in contact with the electroconductive member 10m. The thermal insulator 11 is surrounded by the electroconductive member 10m, for example. With this configuration, the thermal conductance of the structure including the electroconductive member 10m and the thermal insulator 11 is likely to become low, and the electroconductive member 10m is likely to have a desired electric conductivity.

The electroconductive member 10m may be formed to have at least one selected from the group consisting of a hollow and a recess. In this case, the thermal insulator 11 can be disposed so as to fill at least a part of the hollow or at least a part of the recess.

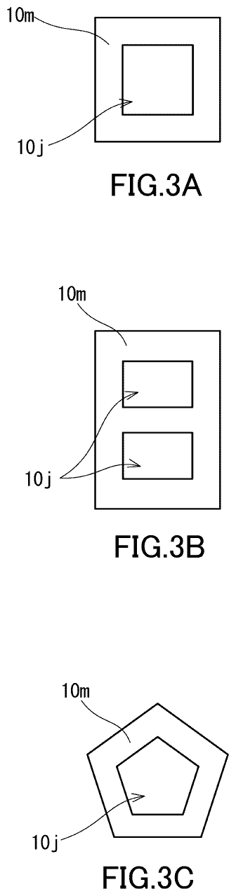

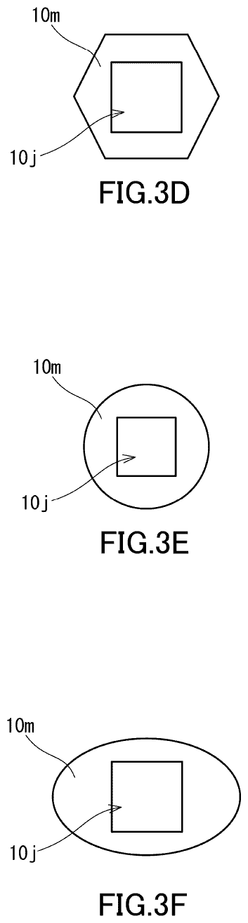

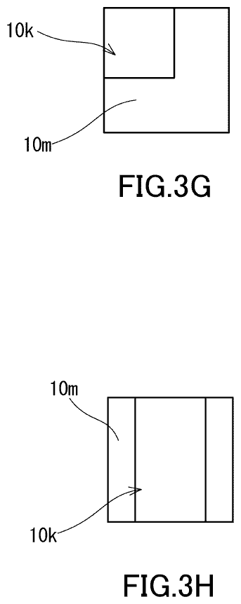

FIG. 3A to FIG. 3H are plan views showing examples of the electroconductive member 10m. In the examples shown in FIG. 3A to FIG. 3F, the electroconductive member 10m has a hollow 10j, for example. The hollow 10j extends in the direction perpendicular to the principal surface of the substrate 20, for example. The hollow 10j may extend through the electroconductive member 10m in the direction perpendicular to the principal surface of the substrate 20, or the hollow 10j may extend separately from at least one of both ends of the electroconductive member 10m in the direction perpendicular to the principal surface of the substrate 20. As shown in FIG. 3B, the electroconductive member 10m may include a plurality of hollows 10j. As shown in FIG. 3A to FIG. 3D, the electroconductive member 10m may have a quadrangular outline such as a square outline and a rectangular outline, a pentagonal outline, or a hexagonal outline in a plan view. The electroconductive member 10m may have another polygonal outline in a plan view. As shown in FIG. 3E and FIG. 3F, the electroconductive member 10m may have a circular outline or an elliptic outline in a plan view. The hollow 10j of the electroconductive member 10m has a polygonal shape such as a quadrangular shape in a plan view, for example. The hollow 10j of the electroconductive member 10m may have a circular shape or an elliptic shape in a plan view, for example.

In the examples shown in FIG. 3G and FIG. 3H, the electroconductive member 10m has a recess 10k, for example. The electroconductive member 10m may have a plurality of recesses 10k. As shown in FIG. 3G, the recess 10k may be separated from one of both ends of the electroconductive member 10m in a direction parallel to the principal surface of the substrate 20. As shown in FIG. 3H, the recess 10k may extend through the electroconductive member 10m in a direction parallel to the principal surface of the substrate 20.

The ratio of the volume of the hollow 10j and the recess 10k to the sum of the volume of the electroconductive member 10m and the volume of the hollow 10j and the recess 10k is not limited to a specific value. The ratio is 50% or greater and 90% or smaller, for example. With this configuration, the thermal conductance of the structure including the electroconductive member 10m and the thermal insulator 11 is likely to become lower, so that the thermal conductance of the entire thermoelectric conversion element 1a is likely to become lower. In addition, the electroconductive member 10m is likely to have a desired electric conductivity.

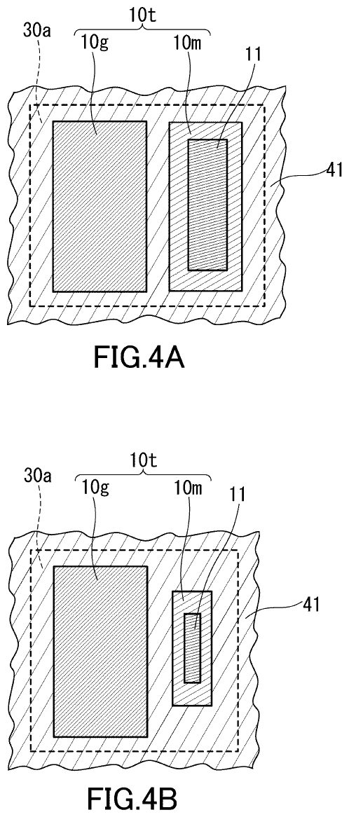

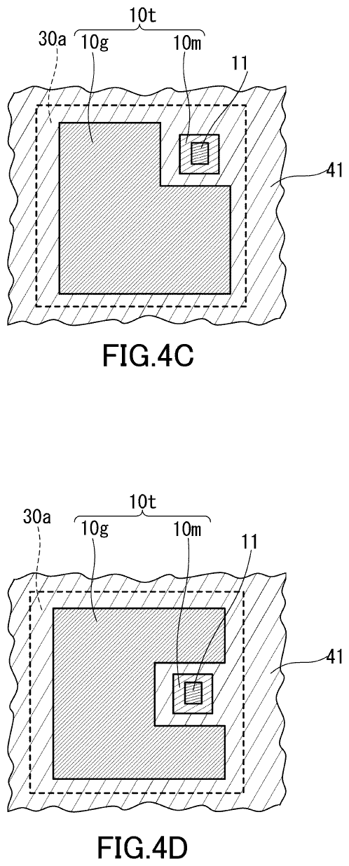

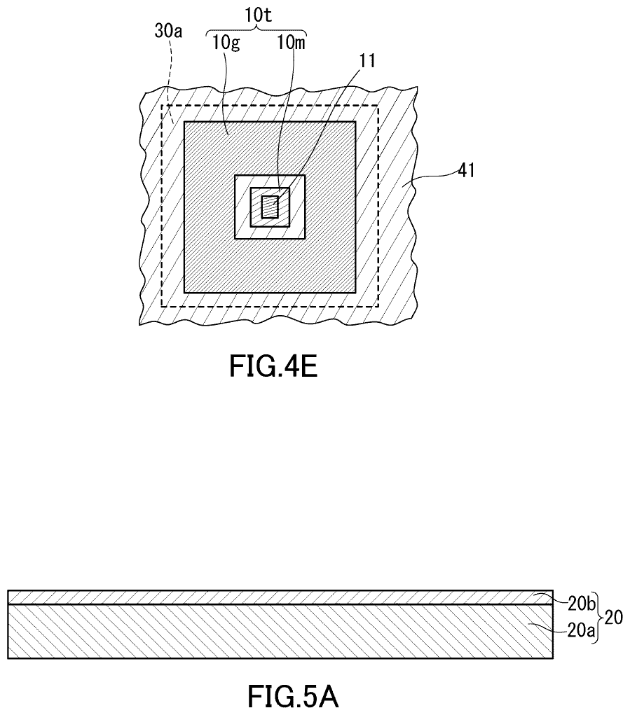

FIG. 4A is a sectional view of the thermocouple 10t taken along line IVA-IVA in FIG. 1A. FIG. 4B to FIG. 4E are sectional views showing other examples of the arrangement of the thermoelectric member 10g and the electroconductive member 10m in the thermocouple 10t of embodiment 1. The outer dimensions of the thermoelectric member 10g and the electroconductive member 10m in a plan view may be the same or different from each other. A side surface of the thermoelectric member 10g and a side surface of the electroconductive member 10m may face each other in one direction as shown in FIG. 4A and FIG. 4B, or may face each other in a plurality of different directions as shown in FIG. 4C, FIG. 4D, and FIG. 4E.

A material forming the base 20a is not limited to a specific material. The base 20a is an Si substrate, for example. The base 20a may be formed by a semiconductor other than Si or a material other than a semiconductor.

A material forming the foundation insulation film 20b is not limited to a specific material. The foundation insulation film 20b may contain an oxide insulator such as silicon oxide and aluminum oxide, or a nitride insulator such as silicon nitride and aluminum nitride. In a case where the base 20a has an electric insulation property, the foundation insulation film 20b may be omitted. The thickness of the foundation insulation film 20b is not limited to a specific value. The thickness may be 50 nm to 1 μm, for example.

Materials forming the first wiring 30a and the second wiring 30b are not limited to specific materials as long as the materials have a predetermined electric conductivity. The first wiring 30a and the second wiring 30b contain metal or a metal compound, for example. Examples of the metal and the metal compound are materials, such as Al, Cu, TiN, and TaN, used in a semiconductor manufacturing process. The thicknesses of the first wiring 30a and the second wiring 30b are not limited to specific values. The thicknesses are 100 nm to 1 μm, for example.

Materials forming the first interlayer insulation film 41 and the second interlayer insulation film 42 are not limited to specific materials. The first interlayer insulation film 41 and the second interlayer insulation film 42 may contain an oxide insulator such as silicon oxide and aluminum oxide, or a nitride insulator such as silicon nitride and aluminum nitride. Materials forming the first interlayer insulation film 41 and the second interlayer insulation film 42 may be a single-crystal material, a polycrystal material, or an amorphous material. Materials forming the first interlayer insulation film 41 and the second interlayer insulation film 42 may be the same kind of material or different kinds of materials. The thickness of the first interlayer insulation film 41 may vary in accordance with the thicknesses of the thermoelectric members 10g. The thickness of the first interlayer insulation film 41 is 100 nm to 10 μm, for example. The thickness of the second interlayer insulation film 42 is not limited to a specific value as long as the second interlayer insulation film 42 can cover the second wiring 30b. The thickness is 100 nm to 2 μm, for example.

Materials forming the plug 53, the first electrode pad 51, and the second electrode pad 52 are not limited to specific materials. The materials are metal or a metal compound, for example. The metal and the metal compound may be materials, such as Al, Cu, W, TiN, and TaN, used in a semiconductor manufacturing process, for example.

As shown in FIG. 1A, the thermoelectric conversion element 1a includes a plurality of the thermocouples 10t, for example. In the thermoelectric conversion element 1a, the thermocouples 10t are connected electrically in series between the first electrode pad 51 and the second electrode pad 52.

In the thermoelectric conversion element of embodiment 1, when a temperature difference arises in the direction perpendicular to the principal surface of the substrate 20, an electromotive force is generated between the first electrode pad 51 and the second electrode pad 52 by the Seebeck effect. Through conductive wires connected to the first electrode pad 51 and the second electrode pad 52, the electromotive force is outputted to outside of the thermoelectric conversion element. Thus, the thermoelectric conversion element can be used as an electric generation device and a heat flow sensor.

In the thermoelectric conversion element of embodiment 1, when conductive wires are connected to the first electrode pad 51 and the second electrode pad 52 and a current is generated, a heat flow in the direction perpendicular to the principal surface of the substrate 20 can be generated by the Peltier effect. The direction of the heat flow can change depending on the direction of the current. Thus, the thermoelectric conversion element of embodiment 1 can be used as a temperature control device for cooling or heating.

An example of a method for manufacturing the thermoelectric conversion element of embodiment 1 will be described. The method for manufacturing the thermoelectric conversion element is not limited to the following method. The method for manufacturing the thermoelectric conversion element of embodiment 1 includes disposing the thermal insulator 11 in contact with the electroconductive member 10m which contains metal or a metal compound and is arranged together with the thin-film-shaped thermoelectric member 10g along the principal surface of the substrate 20. In a case where the electroconductive member 10m has at least one selected from the group consisting of a hollow and a recess, the thermal insulator 11 is disposed so as to fill the hollow or the recess.

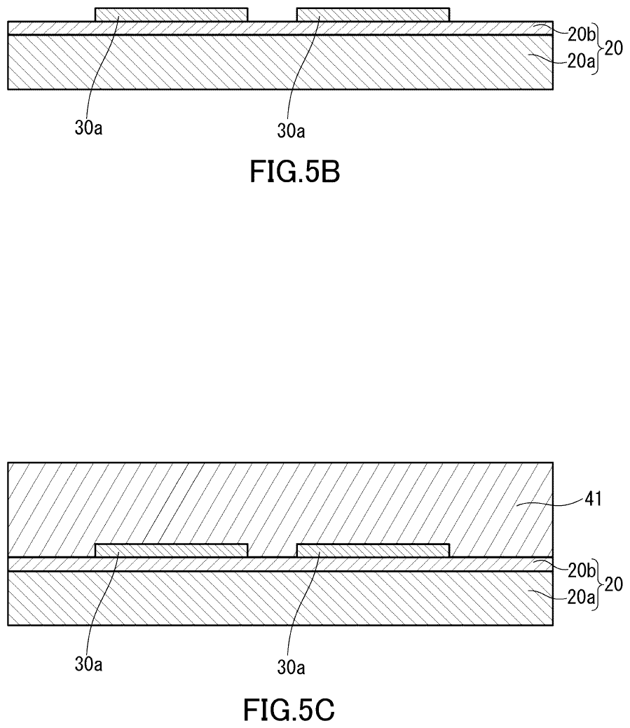

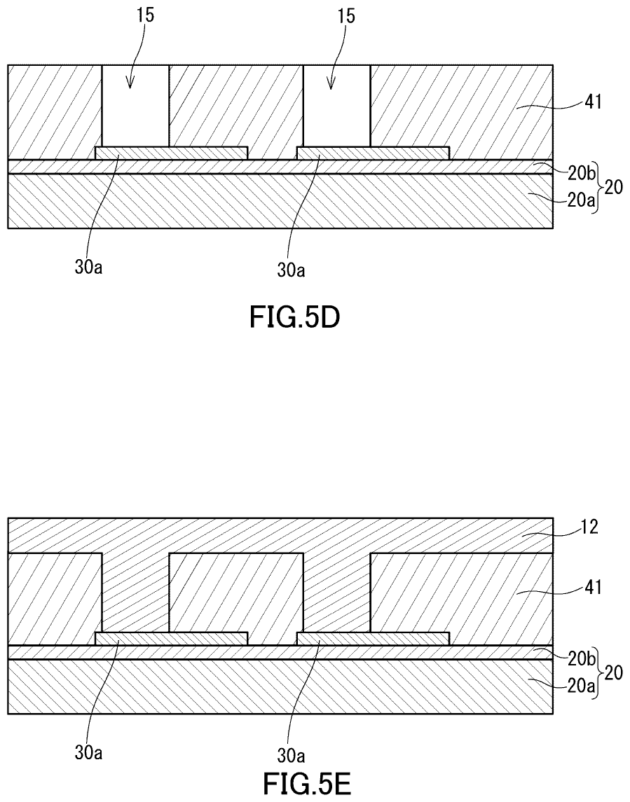

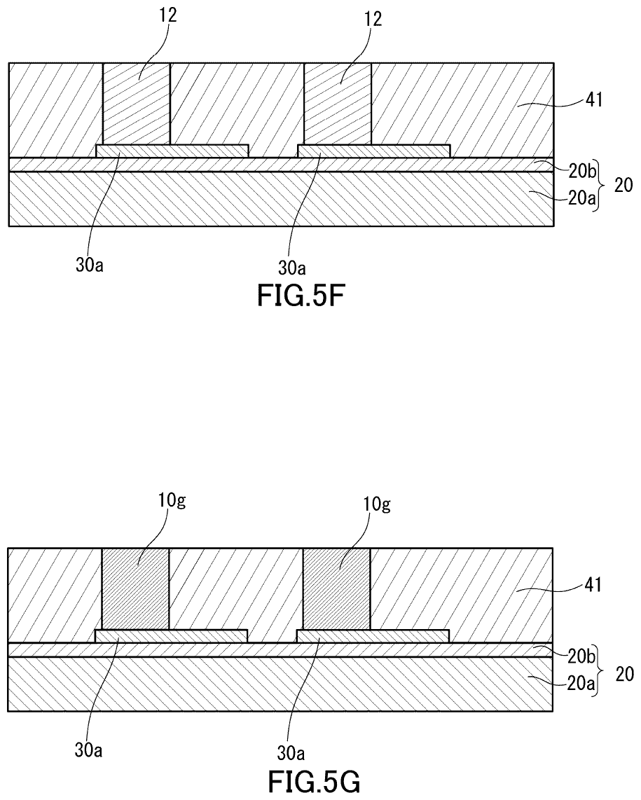

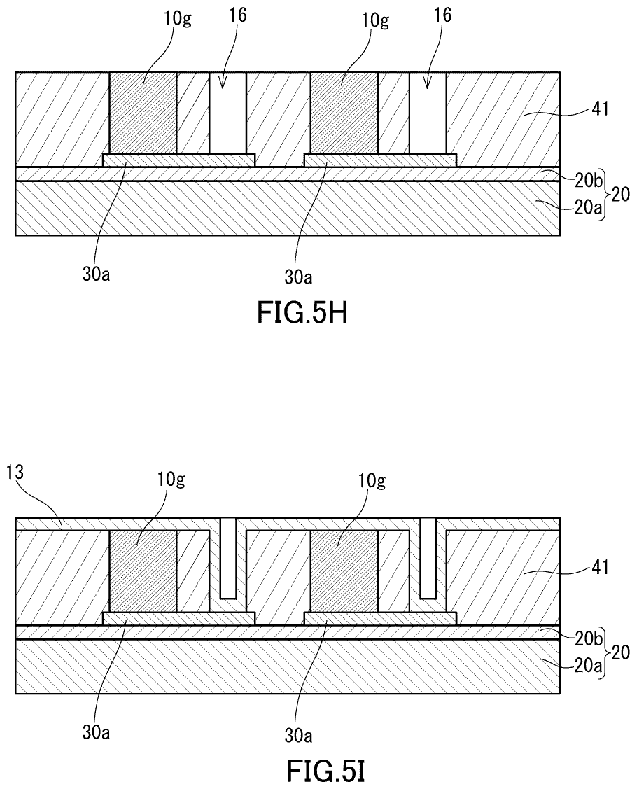

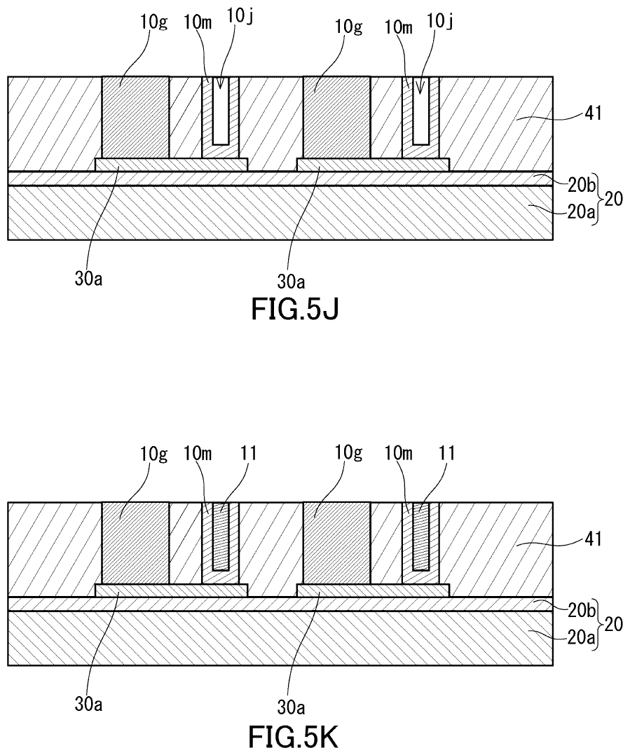

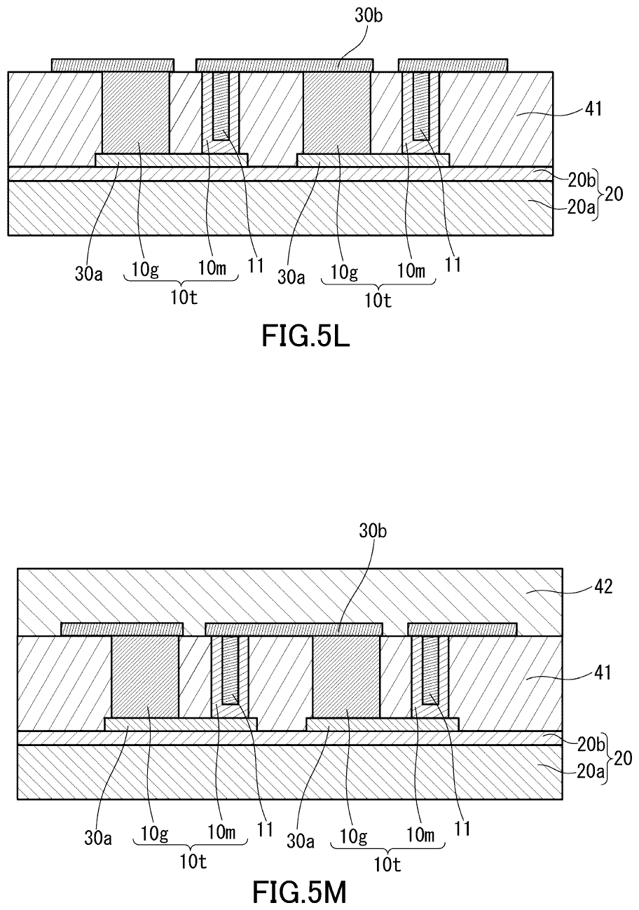

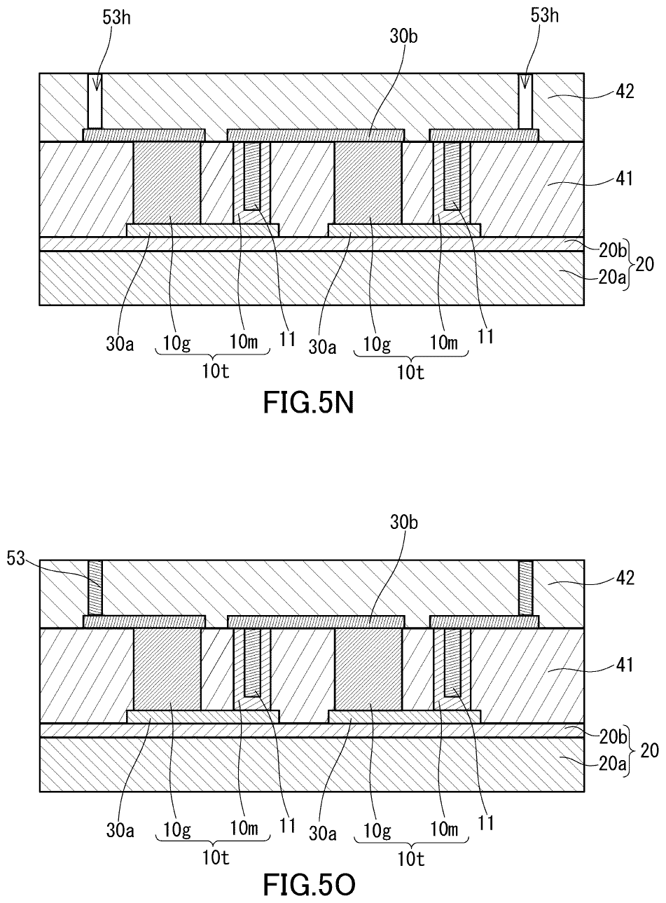

As shown in FIG. 5A, the foundation insulation film 20b made of an electric insulator such as SiO₂ is formed on a surface of the base 20a such as an Si substrate by a method such as sputtering and chemical vapor deposition (CVD), whereby the substrate 20 is obtained. Next, as shown in FIG. 5B, the first wiring 30a made of an electric conductor such as Al is formed. For example, a pattern to be the first wiring 30a is formed by photolithography and etching, or lift-off, from a film of Al or the like formed by a method such as sputtering.

Next, as shown in FIG. 5C, the first interlayer insulation film 41 is formed by a method such as sputtering and CVD, so as to cover the first wiring 30a. Next, as shown in FIG. 5D, recesses 15 are formed in the first interlayer insulation film 41 by photolithography and etching. At this stage, parts of the first wiring 30a are exposed so as to form bottom surfaces of the recesses 15. Next, as shown in FIG. 5E, a thermoelectric material thin film 12 made of a semiconductor such as polycrystal Si is formed by a method such as sputtering and CVD from above the first interlayer insulation film 41, so that the recesses 15 are filled with the thermoelectric material thin film 12. Next, as shown in FIG. 5F, the thermoelectric material thin film 12 outside the recesses 15 is removed by a method such as chemical mechanical polishing (CMP). Next, as shown in FIG. 5G, doping is performed in predetermined areas, whereby the thermoelectric members 10g are obtained. For the doping, a method such as ion implantation is used. An annealing treatment may be additionally performed to adjust the carrier density into a desired range. Each thermoelectric member 10g may be formed as an n-type thermoelectric member having a negative Seebeck coefficient, or a p-type thermoelectric member having a positive Seebeck coefficient. For example, by doping Si with a trivalent element such as phosphorus and arsenic, the thermoelectric member 10g that is an n-type thermoelectric member is obtained. By doping Si with a pentavalent element such as boron and gallium, the thermoelectric member 10g that is a p-type thermoelectric member is obtained.

Next, as shown in FIG. 5H, recesses 16 are formed in the first interlayer insulation film 41 by photolithography and etching. At this stage, parts of the first wiring 30a are exposed so as to form bottom surfaces of the recess 16.

Next, as shown in FIG. 5I, a metal thin film 13 containing metal such as Al is formed by a method such as sputtering and CVD from above the first interlayer insulation film 41. The metal thin film 13 covers the bottom surfaces and side surfaces of the recesses 16. Next, as shown in FIG. 5J, the metal thin film 13 outside the recesses 16 is removed by photolithography and etching, whereby the electroconductive members 10m having the hollows 10j are formed.

Next, at least parts of the hollows 10j are filled with the thermal insulators 11 made of an amorphous material such as SiO₂ by a method such as sputtering and CVD from above the first interlayer insulation film 41. Next, as shown in FIG. 5K, the thermal insulators 11 outside the hollows 10j are removed by a method such as CMP.

Next, as shown in FIG. 5L, the second wiring 30b containing an electric conductor such as Al is formed. For example, a pattern to be the second wiring 30b is formed by photolithography and etching, or lift-off, from a film of Al or the like formed by a method such as sputtering.

Next, as shown in FIG. 5M, the second interlayer insulation film 42 is formed by an electric insulator such as SiO₂ so as to cover the second wiring 30b, by a method such as sputtering and CVD.

For example, the second wiring 30b and the electroconductive members 10m may contain the same kind of material. In this case, the second wiring 30b and the electroconductive members 10m having the hollows 10j may be formed in the same step, by photolithography and etching, or lift-off, after the metal thin film 13 is formed. Then, the second interlayer insulation film 42 containing an electric insulator such as SiO₂ is formed, whereby formation of the second interlayer insulation film 42 and filling with the thermal insulators 11 into the hollows 10j of the electroconductive members 10m can be performed in the same step. In this case, the second interlayer insulation film 42 and the thermal insulators 11 can be formed by the same kind of material.

Next, as shown in FIG. 5N, recesses 53h are formed in the second interlayer insulation film 42 by photolithography and etching. At this stage, parts of the second wiring 30b are exposed so as to form bottom surfaces of the recesses 53h.

Next, a thin film of a material such as Al and TIN is formed by a method such as sputtering and CVD from above the second interlayer insulation film 42, so as to fill the recesses 53h. Next, as shown in FIG. 5O, the thin film outside the recesses 53h is removed by a method such as CMP, whereby the plugs 53 are formed inside the second interlayer insulation film 42. Finally, a metal thin film containing a material such as Al is formed from above the second interlayer insulation film 42, and the first electrode pad 51 and the second electrode pad 52 are formed by lift-off or lithography and etching. Thus, the thermoelectric conversion element of embodiment 1 is obtained.

While the foundation insulation film 20b, the first interlayer insulation film 41, and the second interlayer insulation film 42 are formed of different materials, only the first interlayer insulation film 41 may be finally removed by etching. For example, the first interlayer insulation film 41 may be formed by SiO₂, and the foundation insulation film 20b and the second interlayer insulation film 42 may be formed by Al₂O₃. Then, SiO₂ may be etched by gas-phase hydrofluoric acid, to remove the first interlayer insulation film 41. Owing to removal of the first interlayer insulation film 41 around the thermoelectric member 10g and the electroconductive member 10m, a temperature difference arising between a one-end surface and an other-end surface of each of the thermoelectric member 10g and the electroconductive member 10m in the direction perpendicular to the principal surface of the substrate 20 is likely to become great. As a result, the performance of the thermoelectric conversion element is likely to become higher.

### Embodiment 2

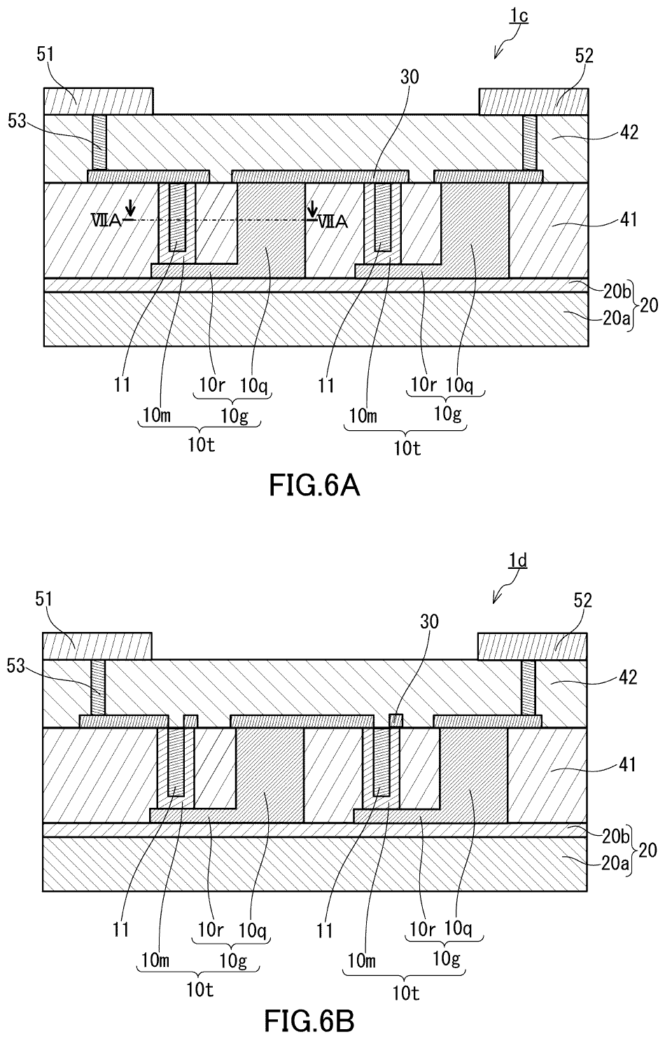

FIG. 6A is a sectional view schematically showing an example of a thermoelectric conversion element of embodiment 2. The thermoelectric conversion element of embodiment 2 is configured in the same manner as the thermoelectric conversion element of embodiment 1, except for specifically described parts. In embodiment 2, components that are the same as or correspond to those of the thermoelectric conversion element of embodiment 1 are denoted by the same reference characters and the detailed description thereof is omitted. The description regarding the thermoelectric conversion element of embodiment 1 also applies to the thermoelectric conversion element of embodiment 2, unless there is technical contradiction therebetween.

As shown in FIG. 6A, in a thermoelectric conversion element 1c, the thermoelectric member 10g has a first portion 10q and a second portion 10r. The first portion 10q has a first thickness. The second portion 10r has a second thickness smaller than the first thickness. In the thermoelectric member 10g, a step is formed by the first portion 10q and the second portion 10r. With this configuration, for example, a configuration corresponding to the first wiring 30a of the thermoelectric conversion element of embodiment 1 can be omitted, whereby the configuration of the thermoelectric conversion element is likely to be simplified.

Each thermoelectric member 10g may contain a p-type thermoelectric material having a positive Seebeck coefficient, or an n-type thermoelectric material having a negative Seebeck coefficient.

The electroconductive member 10m is disposed on the second portion 10r, for example. With this configuration, electric connection between the electroconductive member 10m and the thermoelectric member 10g can be ensured even if a configuration corresponding to the first wiring 30a of the thermoelectric conversion element of embodiment 1 is omitted.

The second portion 10r serves a role equivalent to the first wiring 30a in the thermoelectric conversion element of embodiment 1. The second thickness of the second portion 10r is not limited to a specific value as long as the second thickness is smaller than the first thickness. The second thickness is, for example, 10 nm or greater, and desirably 100 nm or greater.

As shown in FIG. 6A, a wiring 30 is disposed on the thermoelectric members 10g and the electroconductive members 10m. Thus, the thermoelectric members 10g and the electroconductive members 10m are electrically connected, whereby the thermocouples 10t are formed. In the thermoelectric conversion element 1c, the thermal insulators 11 are covered by the wiring 30, for example. FIG. 6B is a sectional view schematically showing another example of the thermoelectric conversion element of embodiment 2. A thermoelectric conversion element 1d shown in FIG. 6B is configured in the same manner as the thermoelectric conversion element 1c, except for specifically described parts. As shown in FIG. 6B, the thermal insulators 11 may not be covered by the wiring 30.

As shown in FIG. 6A, each thermoelectric member 10g is disposed on the foundation insulation film 20b of the substrate 20. Each electroconductive member 10m is disposed on the second portion 10r of the thermoelectric member 10g. The thermoelectric conversion element 1c further includes the first interlayer insulation film 41 and the second interlayer insulation film 42. The first interlayer insulation film 41 is formed so as to fill a gap between the thermoelectric member 10g and the electroconductive member 10m, and a space around the thermoelectric member 10g and the electroconductive member 10m. The second interlayer insulation film 42 is formed on the first interlayer insulation film 41, and covers the wiring 30. The thermoelectric conversion element 1c includes a plurality of plugs 53. The plugs 53 extend through the second interlayer insulation film 42 and are disposed on the wiring 30. The plugs 53 are electrically connected to the wiring 30. The first electrode pad 51 and the second electrode pad 52 are disposed on the second interlayer insulation film 42. The first electrode pad 51 and the second electrode pad 52 are electrically connected to different plugs 53, respectively. Thus, between the first electrode pad 51 and the second electrode pad 52, the thermocouples 10t are electrically connected to the first electrode pad 51 and the second electrode pad 52.

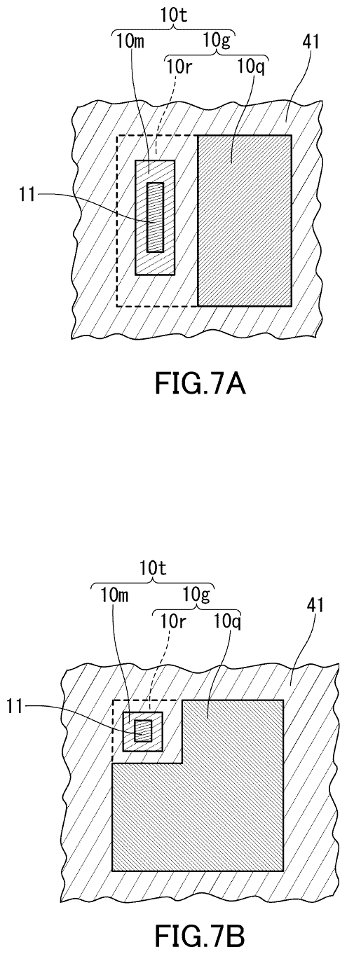

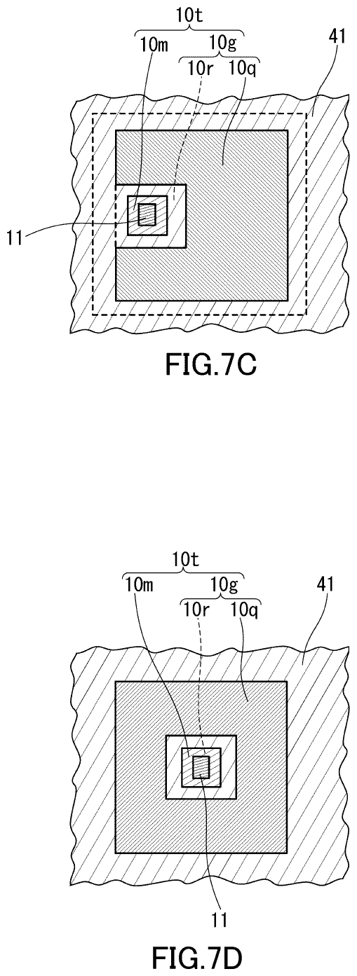

FIG. 7A is a sectional view of the thermocouple 10t taken along line VIIA-VIIA in FIG. 6A. FIG. 7B to FIG. 7D are sectional views showing other examples of the arrangement of the thermoelectric member 10g and the electroconductive member 10m in the thermocouple 10t of embodiment 2. A side surface of the thermoelectric member 10g and a side surface of the electroconductive member 10m may face each other in one direction as shown in FIG. 7A, or may face each other in a plurality of different directions as shown in FIG. 7B, FIG. 7C, and FIG. 7D.

An example of a method for manufacturing the thermoelectric conversion element of embodiment 2 will be described. The method for manufacturing the thermoelectric conversion element of embodiment 2 is not limited to the following method.

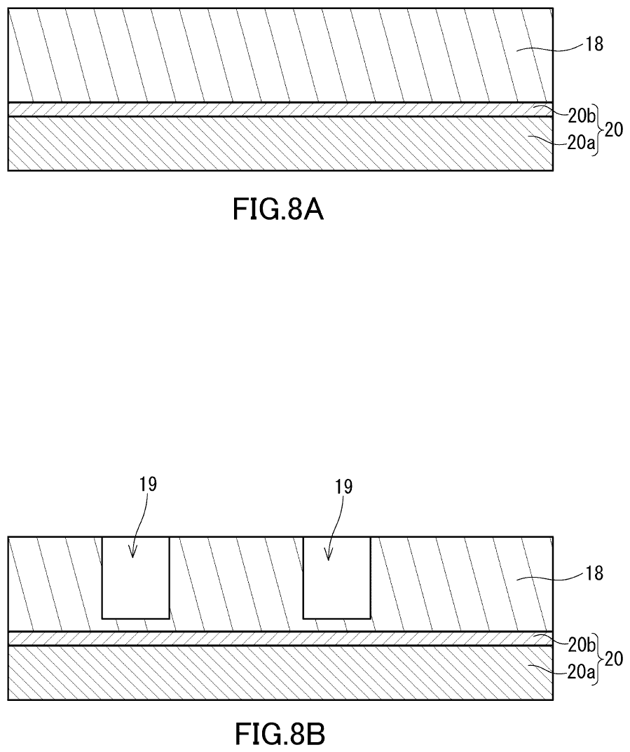

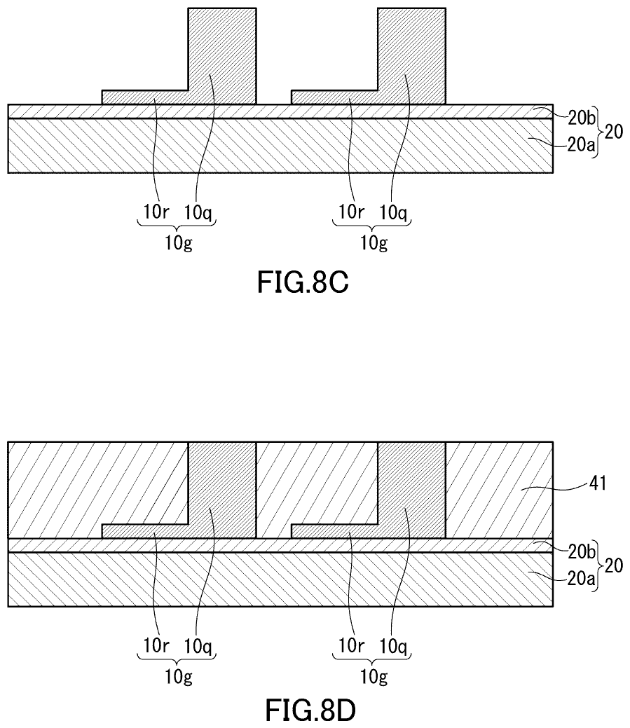

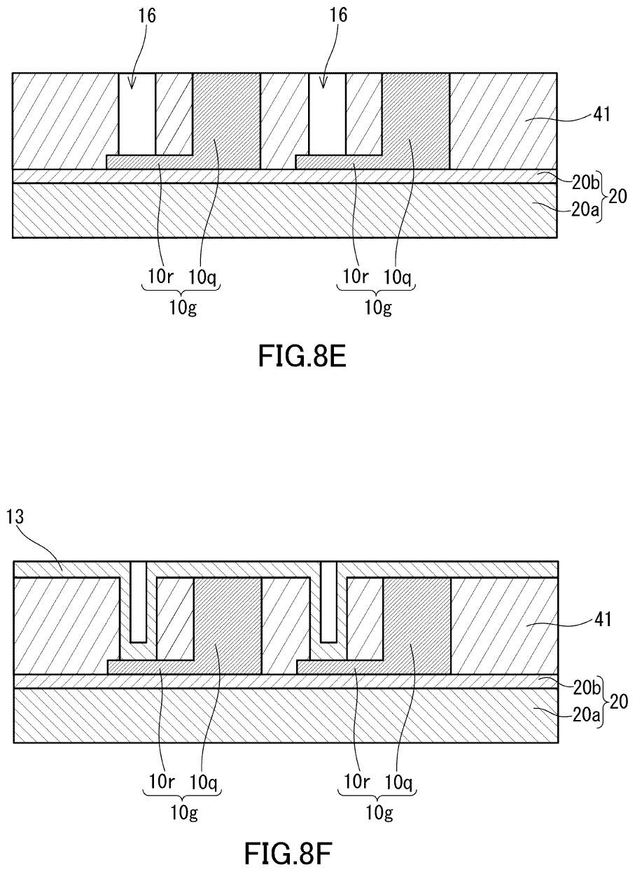

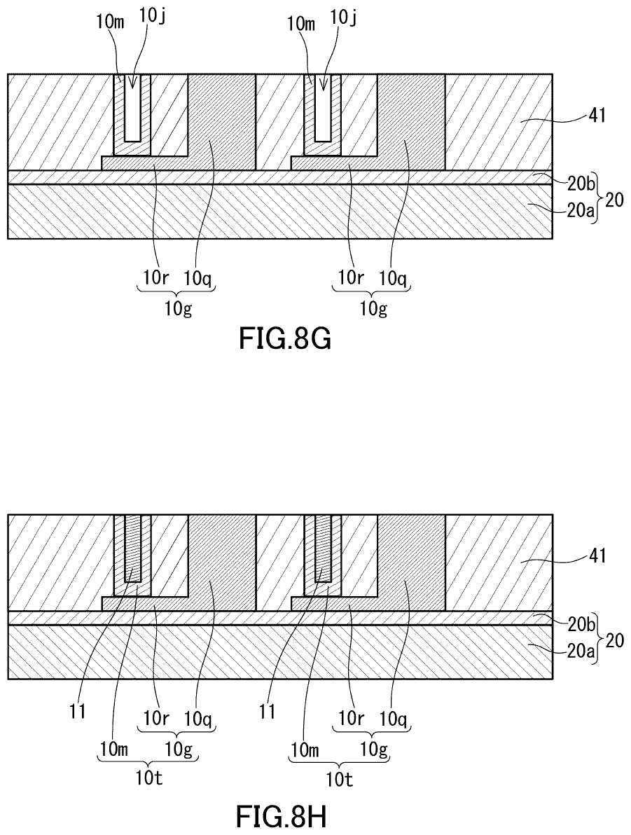

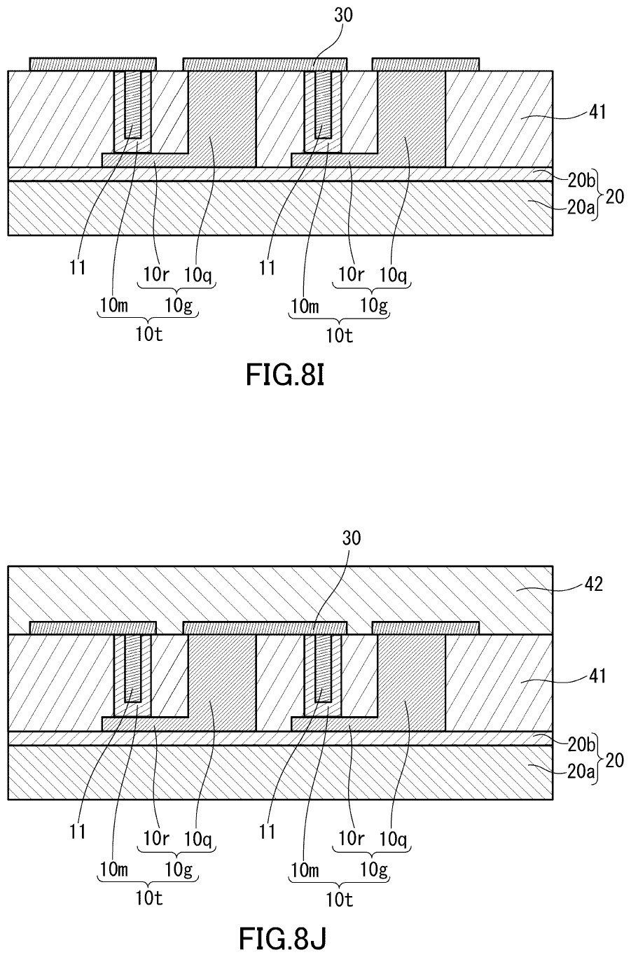

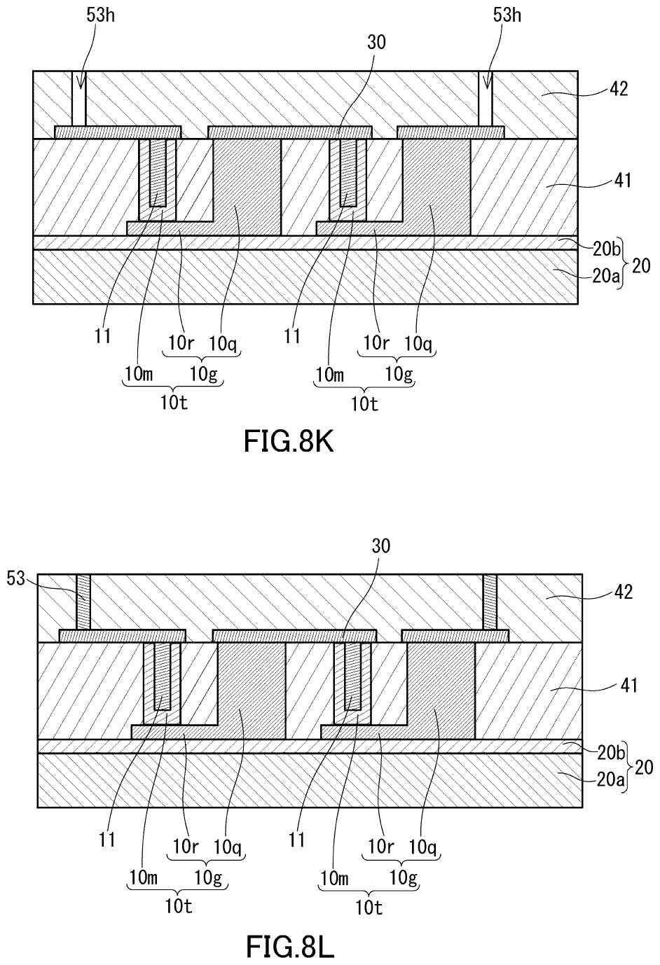

As shown in FIG. 8A, on one principal surface of the base 20a, the foundation insulation film 20b is formed. The base 20a is an Si substrate, for example. The foundation insulation film 20b is an electric insulator such as SiO₂ and is formed by a method such as sputtering or CVD, for example. On the foundation insulation film 20b, the thermoelectric material thin film 18 is formed. The thermoelectric material thin film 18 is a semiconductor such as polycrystal Si and is formed by a method such as sputtering or CVD, for example. A laminate of the base 20a, the foundation insulation film 20b, and the thermoelectric material thin film 18 may be replaced with a silicon-on-insulator (SOI) substrate. In the SOI substrate, a layer corresponding to the foundation insulation film 20b is a layer of SiO₂, and a layer corresponding to the thermoelectric material thin film 18 is a layer of single-crystal Si.

Next, the thermoelectric material thin film 18 is doped with impurity ions and the carrier density of electrons or holes is adjusted into a range of 1×10¹⁹ cm⁻³ to 1×10²¹ cm⁻³. The doping is performed by a method such as ion implantation and thermal diffusion, for example. An annealing treatment may be additionally performed to adjust the carrier density to a desired value. The doping may be performed for the entire surface of the thermoelectric material thin film 18, or may be performed for a predetermined area thereof using photolithography.

Next, as shown in FIG. 8B, recesses 19 are formed in predetermined areas of the thermoelectric material thin film 18 by photolithography and etching. The depths of the recesses 19 are adjusted in consideration of the second thicknesses of the second portions 10r. For example, the etching rate for the thermoelectric material thin film 18 is measured in advance and the time for etching is adjusted on the basis of the measurement result, whereby the depths of the recesses 19 can be adjusted into a range suitable to the second thicknesses of the second portions 10r.

Next, as shown in FIG. 8C, the thermoelectric members 10g are formed by photolithography and etching. Next, the first interlayer insulation film 41 made of a material such as SiO₂ is formed by a method such as sputtering and CVD from above the thermoelectric members 10g, so as to cover the thermoelectric members 10g. Then, as shown in FIG. 8D, of the first interlayer insulation film 41, a portion above the thermoelectric members 10g is removed by a method such as CMP.

Next, as shown in FIG. 8E, recesses 16 are formed in predetermined areas of the first interlayer insulation film 41 by photolithography and etching. At this stage, parts of the second portions 10r are exposed so as to form bottom surfaces of the recesses 16. Next, as shown in FIG. 8F, a metal thin film 13 containing metal such as Al is formed by a method such as sputtering and CVD from above the first interlayer insulation film 41. The metal thin film 13 covers the bottom surfaces and side surfaces of the recesses 16. Next, as shown in FIG. 8G, the metal thin film 13 outside the recesses 16 is removed by photolithography and etching, whereby the electroconductive members 10m having the hollows 10j are formed.

Next, at least parts of the hollows 10j are filled with the thermal insulators 11 made of an amorphous material such as SiO₂ by a method such as sputtering and CVD from above the first interlayer insulation film 41. Next, as shown in FIG. 8H, the thermal insulators 11 outside the hollows 10j are removed by a method such as CMP.

Next, as shown in FIG. 8I, the wiring 30 containing an electric conductor such as Al is formed. For example, a pattern to be the wiring 30 is formed by photolithography and etching, or lift-off, from a film of Al or the like formed by a method such as sputtering.

Next, as shown in FIG. 8J, the second interlayer insulation film 42 is formed by an electric insulator such as SiO₂ so as to cover the wiring 30, by a method such as sputtering and CVD.

For example, in a case where the wiring 30 and the electroconductive members 10m contain the same kind of material, the wiring 30 and the electroconductive members 10m having the hollows 10j may be formed in the same step by photolithography and etching, or lift-off, after the metal thin film 13 is formed. Then, the second interlayer insulation film 42 containing an electric insulator such as SiO₂ is formed, whereby formation of the second interlayer insulation film 42 and filling with the thermal insulators 11 into the hollows 10j of the electroconductive members 10m can be performed in the same step. In this case, the second interlayer insulation film 42 and the thermal insulators 11 can be formed by the same kind of material.

Next, as shown in FIG. 8K, recesses 53h are formed in the second interlayer insulation film 42 by photolithography and etching. Aₜ this stage, parts of the wiring 30 are exposed so as to form bottom surfaces of the recesses 53h.

Next, a thin film of a material such as Al and TiN is formed by a method such as sputtering and CVD from above the second interlayer insulation film 42, so as to fill the recesses 53h. Next, as shown in FIG. 8L, the thin film outside the recesses 53h is removed by a method such as CMP, whereby the plugs 53 are formed inside the second interlayer insulation film 42. Finally, a metal thin film containing a material such as Al is formed from above the second interlayer insulation film 42, and the first electrode pad 51 and the second electrode pad 52 are formed by lift-off or lithography and etching. Thus, the thermoelectric conversion element of embodiment 2 is obtained.

### Additional Notes

From the above description, the following technologies are disclosed.

### Technology 1

A thermoelectric conversion element comprising:
a substrate;
a thermocouple including a thin-film-shaped thermoelectric member and an electroconductive member arranged along a principal surface of the substrate; and
a thermal insulator in contact with the electroconductive member, wherein
the electroconductive member contains at least one selected from the group consisting of metal and a metal compound, and
a thermal conductivity of the thermal insulator is lower than a thermal conductivity of the electroconductive member.

With this configuration, the thermal conductance of the electroconductive member is likely to become low while the manufacturing cost is reduced. Thus, the thermoelectric conversion performance of the uni-leg type thermoelectric conversion element including the thin-film-shaped thermoelectric member is likely to become high.

### Technology 2

The thermoelectric conversion element according to technology 1, wherein the thermal insulator is surrounded by the electroconductive member in a plan view.

With this configuration, the thermal conductance of the structure including the electroconductive member and the thermal insulator is likely to become low and the electroconductive member is likely to have a desired electric conductivity. Thus, the thermoelectric conversion performance of the thermoelectric conversion element is likely to become higher.

### Technology 3

The thermoelectric conversion element according to technology 1 or 2, wherein
a thermal conductivity of the thermal insulator is 10 Wm⁻¹K⁻¹ or lower.

With this configuration, the thermal conductance of the structure including the electroconductive member and the thermal insulator is likely to become lower. Thus, the thermoelectric conversion performance of the thermoelectric conversion element 1a is likely to become higher.

### Technology 4

The thermoelectric conversion element according to any one of technologies 1 to 3, wherein
the thermal insulator contains an amorphous material.

With this configuration, the thermal conductance of the structure including the electroconductive member and the thermal insulator is likely to become lower. Thus, the thermoelectric conversion performance of the thermoelectric conversion element is likely to become higher.

### Technology 5

The thermoelectric conversion element according to any one of technologies 1 to 4, wherein
a ratio of a volume of the thermal insulator to a sum of volumes of the electroconductive member and the thermal insulator is 50% to 90%.

With this configuration, the thermal conductance of the structure including the electroconductive member and the thermal insulator is likely to become lower, so that the thermal conductance of the entire thermoelectric conversion element is likely to become lower. In addition, the electroconductive member is likely to have a desired electric conductivity. Thus, the thermoelectric conversion performance of the thermoelectric conversion element is likely to become higher.

### Technology 6

The thermoelectric conversion element according to any one of technologies 1 to 5, wherein
the thermoelectric member includes a first portion having a first thickness, and a second portion having a second thickness smaller than the first thickness, and
a step is formed by the first portion and the second portion.

With this configuration, a configuration corresponding to the first wiring 30a of the thermoelectric conversion element of embodiment 1 can be omitted. Thus, the configuration of the thermoelectric conversion elements is likely to be simplified.

### Technology 7

The thermoelectric conversion element according to technology 6, wherein
the electroconductive member is disposed on the second portion.

With this configuration, electric connection between the electroconductive member and the thermoelectric member can be ensured even if a configuration corresponding to the first wiring 30a of the thermoelectric conversion element of embodiment 1 is omitted.

### Technology 8

A method for manufacturing a thermoelectric conversion element, comprising disposing a thermal insulator in contact with an electroconductive member which contains at least one selected from the group consisting of metal and a metal compound and is arranged together with a thin-film-shaped thermoelectric member along a principal surface of a substrate, wherein
a thermal conductivity of the thermal insulator is lower than a thermal conductivity of the electroconductive member.

Whit this method, the thermal conductance of the electroconductive member can be reduced by the thermal insulator. Thus, the thermoelectric conversion performance of the thermoelectric conversion element is likely to be enhanced while the manufacturing cost is reduced.

### EXAMPLES

Hereinafter, with reference to Examples, the present embodiment will be described in more detail. However, the thermoelectric conversion element of the present embodiment 1 is not limited to configurations described in the following Examples.

### Samples A-1 to A-10

An Al thin film having a thickness of 100 nm was formed on an SiO₂ thin film having a thickness of 100 nm formed on an Si substrate. Photolithography and etching were performed on the Al thin film, to form a pattern to be a first wiring. Next, an SiO₂ film having a thickness of 1.1 μm was formed so as to cover the first wiring, thus obtaining a first interlayer insulation film. Photolithography and etching were performed on the first interlayer insulation film, to form a recess in the first interlayer insulation film. At this time, a part of the first wiring was exposed so as to form a bottom surface of the recess. Next, a thin film of polycrystal Si was formed and the polycrystal Si outside the recess was removed by CMP, whereby a thermoelectric material thin film was formed in the recess. Next, boron ions were implanted as impurities into the thermoelectric material thin film, with a dosage of 1×10¹⁶ cm⁻², to obtain an Si thermoelectric member. A bottom surface of the Si thermoelectric member had a square shape with each side having a length of 100 μm, and the thickness of the Si thermoelectric member was 1 μm.

Next, a recess was formed in an area adjacent to the Si thermoelectric member in the first interlayer insulation film, by photolithography and etching. Next, an Al thin film was formed on the first interlayer insulation film. The Al thin film was formed so as to cover a bottom surface and a side surface of the recess. Next, while the Al thin film present in an area separated from the recess was removed by photolithography and etching, a part of the Al thin film around the recess and the Al thin film on the Si thermoelectric member were left, to obtain a second wiring. At this stage, an Al member having a hollow surrounded by the Al thin film was formed correspondingly to the recess in a plan view. A bottom surface of the Al member had a square shape with each side having a length of 100 μm, and a height of the Al member which was a dimension of the Al member in a direction perpendicular to a principal surface of the Si substrate was 1 μm. The ratio of the volume of the hollow to the sum of the volume of the Al member and the volume of the hollow was 90%. Next, an SiO₂ thin film was formed from above the hollow, to fill the entirety of the hollow with SiO₂. Finally, SiO₂ around the Si thermoelectric member and the Al member was removed by photolithography and etching, to expose parts of the second wiring. Thus, an element of a sample A-1 was obtained.

### Samples A-2 to A-10

Elements of samples A-2 to A-10 were obtained in the same manner as the sample A-1 except that a formation condition of the Al thin film for creating the Al member was adjusted so that the ratio of the volume of the hollow to the sum of the volume of the Al member and the volume of the hollow became values shown in Table 1. In the sample A-10, the Al member was formed so as not to form the hollow.

### Samples B-1 to B-10

Elements of samples B-1 to B-10 were manufactured in the same manner as the sample A-1 except for the following. In the samples B-1 to B-10, a bottom surface of the Al member had a square shape with each side having a length of 30 μm. In the samples B-1 to B-10, a formation condition of the Al thin film for creating the Al member was adjusted so that the ratio of the volume of the hollow to the sum of the volume of the Al member and the volume of the hollow became values shown in Table 2.

### Samples C-1 to C-10

Elements of samples C-1 to C-10 were manufactured in the same manner as the sample A-1 except for the following. In the samples C-1 to C-10, a bottom surface of the Al member had a square shape with each side having a length of 20 μm. In the samples C-1 to C-10, a formation condition of the Al thin film for creating the Al member was adjusted so that the ratio of the volume of the hollow to the sum of the volume of the Al member and the volume of the hollow became values shown in Table 3.

### Evaluation

The thermoelectric performance of the element of each sample was evaluated and the nondimensionalized performance index ZT thereof at 300 K was determined. The electric resistance of the element of each sample was measured in accordance with a four-terminal method via the first wiring. The thermal conductance of the element of each sample was measured in accordance with a thermoreflectance method. A sample including a polycrystal Si thin film and an Al thin film created on another substrate was separately manufactured, and the Seebeck coefficient of the Si thermoelectric member was determined using the sample and a measurement device ZEM3 manufactured by ULVAC-RIKO, Inc. The value of the Seebeck coefficient was used for determination of the nondimensionalized performance index ZT. Results of these are shown in Tables 1 to 3.

As shown in Table 1, the nondimensionalized performance index ZT of the element of the sample A-4 was equal to or greater than two times that of the element of the sample A-10 having no hollow in the Al member. In the sample A-4, the ratio of the volume of the hollow to the sum of the volume of the Al member and the volume of the hollow was 60%, and the hollow was filled with SiO₂. The thermal conductivity of SiO₂ is lower than the thermal conductivity of Al.

As shown in Table 2, the nondimensionalized performance index ZT of the element of the sample B-3 was equal to or greater than two times that of the element of the sample B-10 having no hollow in the Al member. In the sample B-3, the ratio of the volume of the hollow to the sum of the volume of the Al member and the volume of the hollow was 70%, and the hollow was filled with SiO₂.

As shown in Table 3, the nondimensionalized performance index ZT of the element of the sample C-2 was equal to or greater than two times that of the element of the sample C-10 having no hollow in the Al member. In the sample C-2, the ratio of the volume of the hollow to the sum of the volume of the Al member and the volume of the hollow was 80%, and the hollow was filled with SiO₂.

TABLE 1

| | Ratio of volume of hollow | | | | |
|---|---|---|---|---|---|
| | (SiO₂) to sum of volume of | | | | |
| | Al member and volume of | Seebeck | Electric | Thermal | Nondimensionalized |
| Sample | hollow (SiO₂) | coefficient | resistance | conductance | performance index |
| No. | [%] | [μV/K] | [mΩ] | [W/K] | ZT |
| A-1 | 90 | 401 | 5.03 | 0.30 | 0.0326 |
| A-2 | 80 | 401 | 5.01 | 0.53 | 0.0182 |
| A-3 | 70 | 401 | 5.01 | 0.77 | 0.0126 |
| A-4 | 60 | 401 | 5.01 | 1.00 | 0.0096 |
| A-5 | 50 | 401 | 5.01 | 1.24 | 0.0078 |
| A-6 | 40 | 401 | 5.00 | 1.47 | 0.0066 |
| A-7 | 30 | 401 | 5.00 | 1.71 | 0.0057 |
| A-8 | 20 | 401 | 5.00 | 1.95 | 0.0050 |
| A-9 | 10 | 401 | 5.00 | 2.18 | 0.0044 |
| A-10 | 0 | 401 | 5.00 | 2.42 | 0.0040 |

TABLE 2

| | Ratio of volume of hollow | | | | |
|---|---|---|---|---|---|
| | (SiO₂) to sum of volume of | | | | |
| | Al member and volume of | Seebeck | Electric | Thermal | Nondimensionalized |
| Sample | hollow (SiO₂) | coefficient | resistance | conductance | performance index |
| No. | [%] | [μV/K] | [mΩ] | [W/K] | ZT |
| B-1 | 90 | 401 | 5.30 | 0.07 | 0.1315 |
| B-2 | 80 | 401 | 5.15 | 0.09 | 0.1037 |
| B-3 | 70 | 401 | 5.10 | 0.11 | 0.0849 |
| B-4 | 60 | 401 | 5.08 | 0.13 | 0.0717 |
| B-5 | 50 | 401 | 5.06 | 0.15 | 0.0620 |
| B-6 | 40 | 401 | 5.05 | 0.18 | 0.0546 |
| B-7 | 30 | 401 | 5.04 | 0.20 | 0.0488 |
| B-8 | 20 | 401 | 5.04 | 0.22 | 0.0441 |
| B-9 | 10 | 401 | 5.03 | 0.24 | 0.0402 |
| B-10 | 0 | 401 | 5.03 | 0.26 | 0.0370 |

TABLE 3

| | Ratio of volume of hollow | | | | |
|---|---|---|---|---|---|
| | (SiO₂) to sum of volume of | | | | |
| | Al member and volume of | Seebeck | Electric | Thermal | Nondimensionalized |
| Sample | hollow (SiO₂) | coefficient | resistance | conductance | performance index |
| No. | [%] | [μV/K] | [mΩ] | [W/K] | ZT |
| C-1 | 90 | 401 | 5.68 | 0.06 | 0.1496 |
| C-2 | 80 | 401 | 5.34 | 0.07 | 0.1365 |
| C-3 | 70 | 401 | 5.23 | 0.08 | 0.1221 |
| C-4 | 60 | 401 | 5.17 | 0.09 | 0.1098 |
| C-5 | 50 | 401 | 5.14 | 0.09 | 0.0995 |
| C-6 | 40 | 401 | 5.11 | 0.10 | 0.0909 |
| C-7 | 30 | 401 | 5.10 | 0.11 | 0.0836 |
| C-8 | 20 | 401 | 5.09 | 0.12 | 0.0774 |
| C-9 | 10 | 401 | 5.08 | 0.13 | 0.0720 |
| C-10 | 0 | 401 | 5.07 | 0.14 | 0.0673 |

### INDUSTRIAL APPLICABILITY

The thermoelectric conversion element of the present disclosure is applicable to various purposes including purposes of electric generation and temperature control, for example.

What is claimed is:

1. A thermoelectric conversion element comprising:
a substrate;
a thermocouple including a thin-film-shaped thermoelectric member and an electroconductive member arranged along a principal surface of the substrate; and
a thermal insulator in contact with the electroconductive member, wherein
the electroconductive member contains at least one selected from the group consisting of metal and a metal compound, and
a thermal conductivity of the thermal insulator is lower than a thermal conductivity of the electroconductive member.

2. The thermoelectric conversion element according to claim 1, wherein
the thermal insulator is surrounded by the electroconductive member in a plan view.

3. The thermoelectric conversion element according to claim 1, wherein
a thermal conductivity of the thermal insulator is 10 Wm⁻¹K⁻¹ or lower.

4. The thermoelectric conversion element according to claim 1, wherein
the thermal insulator contains an amorphous material.

5. The thermoelectric conversion element according to claim 1, wherein
a ratio of a volume of the thermal insulator to a sum of volumes of the electroconductive member and the thermal insulator is 50% to 90%.

6. The thermoelectric conversion element according to claim 1, wherein
the thermoelectric member includes a first portion having a first thickness, and a second portion having a second thickness smaller than the first thickness, and
a step is formed by the first portion and the second portion.

7. The thermoelectric conversion element according to claim 6, wherein
the electroconductive member is disposed on the second portion.

8. A method for manufacturing a thermoelectric conversion element, comprising disposing a thermal insulator in contact with an electroconductive member which contains at least one selected from the group consisting of metal and a metal compound and is arranged together with a thin-film-shaped thermoelectric member along a principal surface of a substrate, wherein
a thermal conductivity of the thermal insulator is lower than a thermal conductivity of the electroconductive member.
